(19) United States
(12) Patent Application Publication
(10) Pub. No.: US 2013/0250984 A1
(43) Pub. Date: Sep. 26, 2013

(54) LASER ELEMENT HAVING A THERMALLY CONDUCTIVE JACKET

(71) Applicant: AMS RESEARCH CORPORATION, Minnetonka, MN (US)

(72) Inventors: Rongwei Jason Xuan, Fremont, CA (US); Douglas L. Evans, Andover, MN (US)

(73) Assignee: AMS Research Corporation, Minnetonka, MN (US)

(21) Appl. No.: 13/753,069

(22) Filed: Jan. 29, 2013

Related U.S. Application Data
(60) Provisional application No. 61/614,127, filed on Mar. 22, 2012.

(51) Int. Cl. H01S 5/024

(52) U.S. Cl. CPC H01S 5/024
USPC 372/34; 372/35

(57) ABSTRACT

A laser element includes a laser rod and a thermally conductive jacket on an exterior surface of the laser rod. The thermally conductive jacket assists in dissipating heat generated in the laser rod during the application of pump energy to the laser rod.

### CROSS-REFERENCE TO RELATED APPLICATION

The present application is based on and claims the benefit of U.S. provisional patent application Ser. No. 61/614,127, filed Mar. 22, 2012, the content of which is hereby incorporated by reference in its entirety.

### BACKGROUND

Embodiments of the present invention generally relate to laser systems and, more specifically, to a laser element for use in a laser system having a thermally conductive jacket.

High power laser systems have a broad range of applications throughout the scientific, industrial and medical fields. Laser systems generally include a pump source, a laser element and a laser resonator. The pump source may include laser diodes or bars that generate pump energy or a light input to the laser element. The laser element absorbs the pump energy and emits laser light responsive to the absorbed energy. The laser resonator operates to generate a harmonic of the laser light.

The laser element is generally tuned to absorb pump energy having a wavelength that is within a specified operating band and discharge a laser beam in response to the pump energy. This process generates heat in the laser element. A chiller is generally used to circulate a flow of cooling liquid around the laser element and other components of the system, such as the pump source, to maintain the components within a desired temperature range.

For end-pumped solid state laser system, the end of the laser element that receives the pump energy becomes hotter than other portions of the laser element. In high power laser systems, temperature gradients develop in the laser element. These temperature gradients produce stresses in the laser element that can become large enough to break the laser element at high pump energy input levels. As a result, the power of the pump energy must be limited to avoid breaking the laser element. This results in a limitation to the power of the laser output from the system.

### SUMMARY

Embodiments of the invention are directed to a laser element, a laser system that uses the laser element, and a method of operating the laser system. In some embodiments, the laser element comprises a laser rod and a thermally conductive jacket on an exterior surface of the laser rod. The thermally conductive jacket assists in dissipating heat generated in the laser rod during the application of pump energy to the laser rod.

Embodiments of the laser system include the laser element described above, a chiller and a pump source. The chiller is configured to deliver a flow of cooling liquid over the thermally conductive jacket of the laser element. The pump source is configured to pump an end of the laser rod with pump energy. The laser rod generates laser light in response to the pump energy and heat from the laser rod is conducted through the jacket to the flow of cooling liquid.

In some embodiments of the method, a flow of cooling liquid is delivered over a laser element comprising a thermally conductive jacket on an exterior surface of a laser rod. The laser rod is pumped with pump energy generated by a pump source. Laser light is generated using the laser rod in response to the pump energy. Heat is conducted from the laser rod to the flow of cooling liquid through the thermally conductive jacket.

This Summary is provided to introduce a selection of concepts in a simplified form that are further described below in the Detailed Description. This Summary is not indented to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 is a simplified diagram of an exemplary laser system in accordance with the embodiments of the invention.

FIG. 2 is a simplified side cross-sectional view of a laser element in accordance with embodiments of the invention supported within a cooling chamber housing of a chiller and end pumped by a pump source.

FIG. 3 is a flowchart illustrating a method of operating a laser system in accordance with embodiments of the invention.

### DETAILED DESCRIPTION OF ILLUSTRATIVE EMBODIMENTS

Embodiments of the invention are described more fully hereinafter with reference to the accompanying drawings. The various embodiments of the invention may, however, be embodied in many different forms and should not be construed as limited to the embodiments set forth herein. Rather, these embodiments are provided so that this disclosure will be thorough and complete, and will fully convey the scope of the invention to those skilled in the art. Elements that are identified using the same or similar reference characters refer to the same or similar elements.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, if an element is referred to as being “directly connected” or “directly coupled” to another element, there are no intervening elements present.

It will be understood that, although the terms first, second, etc. may be used herein to describe various elements, these elements should not be limited by these terms. These terms are only used to distinguish one element from another. Thus, a first element could be termed a second element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

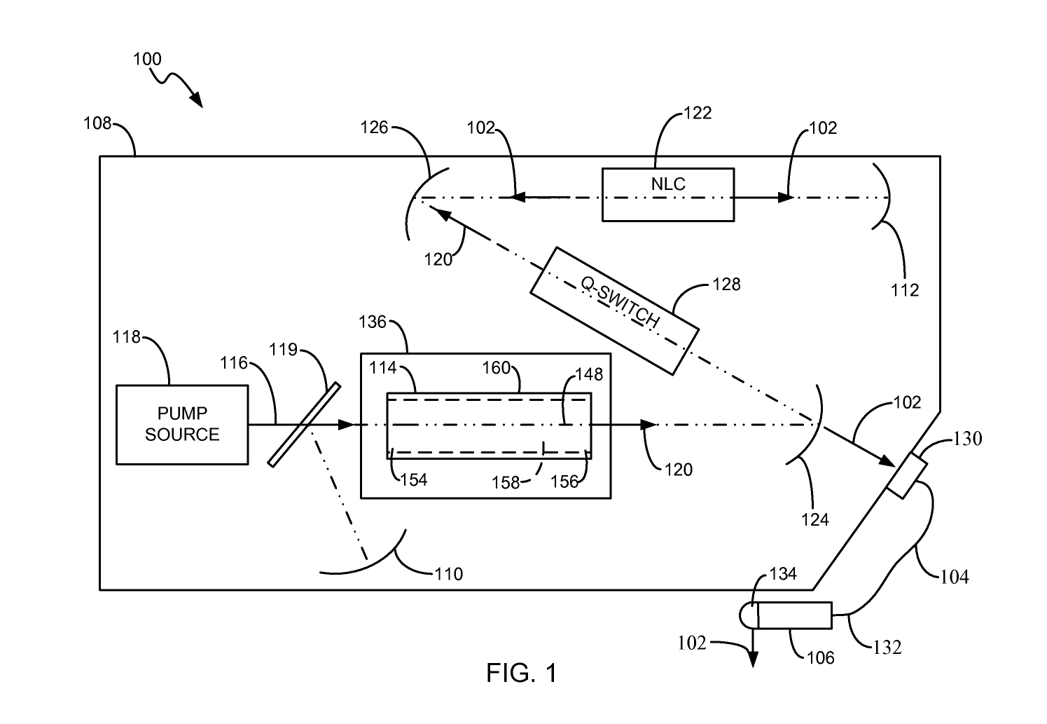

FIG. 1 is a simplified diagram of an exemplary surgical laser system 100 in accordance with embodiments of the invention. In general, the laser system 100 is configured to generate electromagnetic radiation 102 in the form of a laser beam, deliver the electromagnetic radiation through a laser fiber 104, such as a waveguide or optical fiber, to a probe tip 106 where it is discharged to a desired target, such as tissue of a patient.

The exemplary system 100 comprises a laser resonator 108. The laser resonator 108 may include a first resonator mirror 110, a second resonator minor 112 and a laser rod or element 114 formed in accordance with embodiments of the invention. In one embodiment, the laser element 114 comprises a yttrium-aluminum-garnet (YAG) crystal rod with neodymium (Nd) atoms dispersed therein to form a Nd:YAG laser rod. Other features of the laser element 114 are described below.

The laser element 114 is pumped by a pump energy 116 from a pump source 118, such as diode stack or other conventional pump source, through a folding mirror 119 and possibly pump energy re-shaping optics (not shown). The laser element 114 generates laser light or beam 120 at a first frequency in response to the pump energy 116. The laser element 114 has optical gain at certain wavelengths and this determines the wavelength of the laser beam 120 inside the resonator 108. This wavelength is also referred to as the fundamental wavelength. For the Nd:YAG laser rod, the typical fundamental wavelength is 1064 nm.

In some embodiments, the laser beam 120 bounces back and forth between the first and second resonator mirrors 110 and 112 along a route determined by intermediary mirrors, such as minor 124, a folding mirror 119 and a mirror 126. The laser beam 120 propagates through the laser element 114 and a nonlinear crystal 122. Exemplary embodiments of the nonlinear crystal 122 include a lithium borate (LBO) crystal or a potassium titanyl phosphate crystal (KTP). The nonlinear crystal 122 generates a second harmonic of the laser beam 120 emitted by the laser element 114.

When the laser beam 120 inside the resonator 108 propagates through the nonlinear crystal 122 in a direction away from the folding mirror 124 and toward the second resonator minor 112, a beam 102 of electromagnetic radiation at the second harmonic wavelength is output from the crystal 122. The second resonator mirror 112 is highly reflective at both the fundamental and second harmonic wavelengths, and both beams 120 and 102 propagate back through the nonlinear crystal 122. On this second pass, more beams 102 at the second harmonic wavelength are produced. For example, the nonlinear crystal 122 can produce a laser beam 102 having a wavelength of approximately 532 nm (green) when a Nd:YAG rod is used in the laser element 114. One advantage of the 532 nm wavelength is that it is strongly absorbed by hemoglobin in blood and, therefore, is useful for cutting, vaporizing and coagulating vascular tissue.

In some embodiments, the system 100 includes a Q-switch 128 that converts the laser beam 120 to a train of short pulses with high peak power. These short pulses increase the conversion efficiency of the second harmonic laser beam 102 and increase the average power of the laser beam 102 outside the resonator 108.

The minor 124 is highly reflective at the fundamental wavelength and is highly transmissive at the second harmonic wavelength. Thus, the laser beam 102 at the second harmonic passes through the minor 124 and produces a second harmonic laser beam 102 outside the optical resonator 108. The laser fiber 104 connects to an optical coupler 130, which couples the beam 102 to the laser fiber 104 through a shutter mechanism (not shown). The beam 102 travels through the laser fiber 104 to the probe 106 coupled to a distal end 132 of the laser fiber 104. Embodiments of the probe 106 include components that support the distal end 132 of the laser fiber, such as an endoscope or cystoscope.

In some embodiments, the probe 106 includes a probe tip 134 where the laser beam 102 is discharged. In some embodiments, the probe tip 134 includes a fiber cap that is attached to the distal end of the optical fiber 104. The laser energy may be directed along the axis of the probe 106 (i.e., end firing probe), laterally from the probe tip 134 (i.e., side-firing probe), or in another conventional manner.

The laser system 100 may be controlled by a surgeon through a suitable interface. The controls include a controller for selectively opening the shutter mechanism of the system 100 to allow for continuous or pulsed discharge of the laser beam 102 through the probe 106.

In some embodiments, the system 100 includes a chiller 136 that operates to maintain the diode stack 118, the Q-switch 128 and/or the laser element 114 within a desired temperature range using a flow of cooling liquid. The chiller 136 may be formed in accordance with conventional laser system chillers.

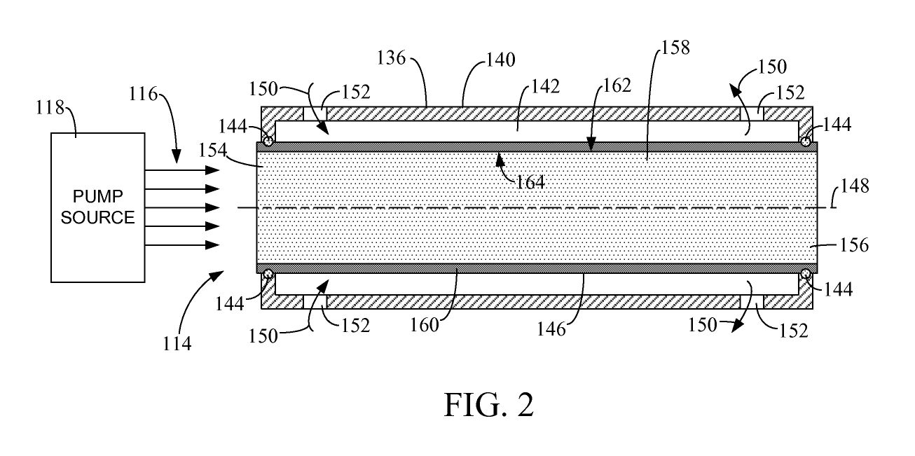

In some embodiments, the laser element 114 is supported within a housing 140 of the chiller 136, as shown in FIG. 2. The housing 140 defines a cooling chamber 142 and may be sealed around the laser element 114 using O-rings 144, or other suitable technique. In some embodiments, the cooling chamber 142 surrounds the sides or sidewall 146 of the laser element 114 extending along a central axis 148, as shown in FIG. 2. A flow of cooling liquid, represented by arrows 150, is circulated around the laser element 114 within the chamber 142. In some embodiments, the housing includes ports 152 through which the flow 150 enters and exits the chamber 142.

The laser element 114 is pumped by pump energy 116 from the pump source 118 from an end 154 of the laser element 114, as shown in FIG. 2. The end pumping of the laser element 114 causes heat to be generated at the end 154. In some embodiments, the flow of cooling liquid 150 operates to maintain the laser element 114 within a desired temperature range.

With conventional laser elements, the heat generated at the pumped end 154 is conducted along the direction of the central axis 148 (FIG. 2) of the laser element. The uneven distribution of the heat and the uneven cooling of the laser element 114 by the chiller 136 results in the formation of temperature gradients between the hot pumped end 144 and the relatively cooler opposing end 156 of the laser element. At sufficient pump energy levels, these temperature gradients can produce stresses in the laser element that break the laser element.

Embodiments of the laser element 114 have improved heat dissipation along the central axis 148 of the laser element 114, and improved efficiency at which heat may be dissipated from the laser element 114. In some embodiments, the laser element 114 includes a laser rod 158, as shown in FIG. 2. Exemplary embodiments of the laser rod 158 include a Nd:YAG laser rod as described above, a thulium-doped yttrium aluminum garnet (Tm:YAG) laser rod, a ytterbium-doped yttrium aluminum garnet (Yb:YAG) laser rod, a holmium-doped yttrium aluminum garnet (Ho:YAG) laser rod, or other conventional laser rod. In some embodiments, the laser element 114 includes a thermally conductive jacket 160 that engages the rod 158. In some embodiments, the jacket 160 is a cylindrical jacket that engages the exterior surface 162 of the laser rod 158 along the side 146, as shown in FIG. 2.

In some embodiments, the jacket 160 operates to conduct heat along the central axis 148 of the rod 158. This increases the efficiency at which heat generated at the end 154 pumped by the pump energy 116 is distributed along the length of the rod 158 and reduces temperature gradients in the rod 158. Consequently, the laser element 114 may be pumped with pump energy 116 having a higher power while avoiding laser rod 158 breakage than would be possible with conventional laser elements. Thus, the laser element 114 allows the system 100 to produce higher energy output laser beams 102.

The jacket 160 also increases the surface area of the laser element 114 that is exposed to the cooling water of the chiller 136. In some embodiments, the jacket includes fins or other projections (not shown) to increase heat dissipation. As a result, heat transfer between the laser rod 158 and the cooling water flow 150 of the chiller 136 is increased. This allows the chiller 136 to operate at a higher temperature for a given pump energy 116 than would be possible with conventional laser elements, resulting in an energy savings.

In some embodiments, the jacket 160 forms a barrier between the rod 158 and the flow of cooling liquid 150. This allows the chiller 136 to use different liquids than the conventional deionized water, which may further improve the efficiency of the laser system 100.

As a result, the chiller 136 can operate at a lower power level than would be possible using the laser rod 158 without the jacket 160. The improved heat transfer due to the cooling jacket 160 using special liquid instead of water can also reduce the risk of creating a condensing environment in the laser resonator 108.

The more efficient cooling of the laser rod 158 and the reduction of thermal stresses in the rod 158 due to the jacket 160, allows the laser rod 158 to accept pump energy 116 of a wider dynamic range than would otherwise be possible using conventional laser elements. Additionally, the laser rod 158 can receive a higher pump energy 116 than would be possible using conventional laser elements. As a result, one may produce a desired laser output using a smaller laser rod 158 than would be possible using conventional designs resulting in a cost savings and higher laser gain.

The cooling jacket 160 comprises a thermally conductive material that is more thermally conductive than the laser rod 158. In some embodiments, the jacket 160 has a coefficient of thermal expansion that is the same or similar to that of the laser rod 158. In some embodiments, the jacket 160 comprises metal. In some embodiments, the jacket 160 comprises silver, gold, copper alloy, and/or aluminum nitride.

In some embodiments, the jacket 160 is in the form of a cylindrical sleeve that receives the rod 158. In some embodiments, the jacket 160 is in the form of a coating that is applied to the exterior surface 162 of the rod 158. In some embodiments, the coating is applied to the exterior surface 162 of the laser rod 158 through a dipping process, through chemical vapor deposition, or other suitable technique. In some embodiments, the jacket 160 has a thickness of approximately 0.002-0.020 inch.

In some embodiments, the jacket 160 forms a reflective interior surface 164 that faces the exterior surface 162 of the rod 158. The reflective surface 164 operates to reduce heat production from exposure of the jacket 160 to the pump energy 116 and/or the beam 120.

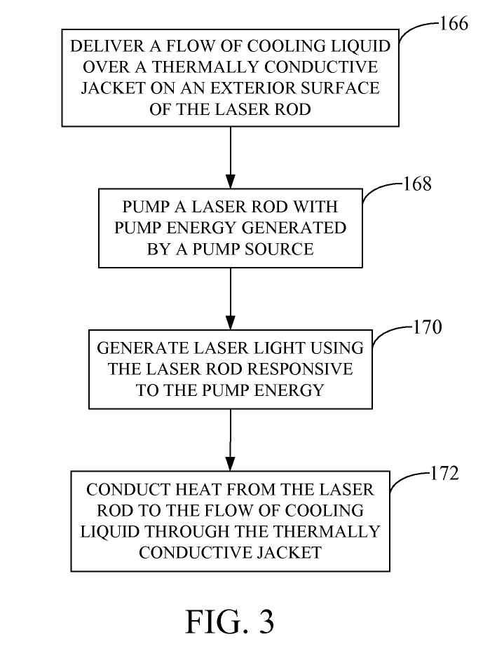

FIG. 3 is a flowchart illustrating a method of operating the system 100 in accordance with embodiments of the invention. At 166, a flow of cooling liquid 150 (FIG. 2) is delivered over a thermally conductive jacket 160 on the exterior surface 162 of the laser rod 158. The jacket 160 is formed in accordance with one or more embodiments discussed above. In some embodiments, the flow 150 travels through a cooling chamber 142 defined by a housing 140 of a chiller 136. In some embodiments, the jacket 160 prevents the flow 150 from contacting the exterior surface 162 of the laser rod 148.

At 168, a laser rod 114 is pumped with pump energy 116 generated by a pump source 118, as discussed above with reference to FIGS. 1 and 2. In some embodiments, the pump energy 116 is delivered to an end 154 of the laser rod 158. At 170, laser light 120 (FIG. 1) is generated using the laser rod responsive to the pump energy 116.

At 172, heat form the laser rod 158 is conducted to the flow of cooling liquid 150 through the jacket 160. As discussed above, the thermally conductive jacket 160 improves the efficiency at which heat is dissipated from the laser rod 158 to the flow of cooling liquid 150 compared to conventional laser elements. Additionally, the thermally conductive jacket 160 may reduce stresses in the laser rod 158 due to improved heat dissipation along the length of the laser rod 158. The improved heat dissipation resulting from the use of the jacket 160 allows the laser system 100 to discharge higher power laser beams 102 than conventional laser systems using the same laser rod.

Although the present invention has been described with reference to preferred embodiments, workers skilled in the art will recognize that changes may be made in form and detail without departing from the spirit and scope of the invention.

What is claimed is:

1. A laser element for use in a laser system comprising:
a laser rod; and
a thermally conductive jacket on an exterior surface of the laser rod.

2. The laser element of claim 1, wherein:
the laser rod has a central axis; and
the jacket surrounds the exterior surface of the laser rod extending along the central axis.

3. The laser element of claim 2, wherein the thermally conductive jacket is bonded to the exterior surface.

4. The laser element of claim 3, wherein the thermally conductive jacket comprises a metal selected from the group consisting of silver, gold, copper alloy, and aluminum nitride.

5. The laser element of claim 3, wherein the thermally conductive jacket has a thickness in the range of 0.002-0.020 inch.

6. The laser element of claim 1, wherein the laser rod is selected from the group consisting of a neodymium-doped yttrium aluminum garnet (Nd:YAG) laser rod, a thulium-doped yttrium aluminum garnet (Tm:YAG) laser rod, a ytterbium-doped yttrium aluminum garnet (Yb:YAG) laser rod, and a holmium-doped yttrium aluminum garnet (Ho:YAG) laser rod.

7. The laser element of claim 1, wherein the thermally conductive jacket comprises a reflective surface facing the exterior surface of the laser rod.

8. A laser system comprising:
a laser element comprising:
a laser rod; and
a thermally conductive jacket on an exterior surface of the laser rod;
a chiller configured to deliver a flow of cooling liquid over the thermally conductive jacket; and
a pump source configured to pump an end of the laser rod with pump energy;
wherein:
the laser rod generates laser light in response to the pump energy; and
heat from the laser rod is conducted through the jacket to the flow of cooling liquid.

9. The laser system of claim 8, wherein:
the laser rod has a central axis; and
the jacket surrounds the exterior surface of the laser rod extending along the central axis.

10. The laser system of claim 9, wherein the thermally conductive jacket is bonded to the exterior surface.

11. The laser system of claim 9, wherein the thermally conductive jacket comprises a metal selected from the group consisting of silver, gold, copper alloy, and aluminum nitride.

12. The laser system of claim 9, wherein the thermally conductive jacket has a thickness in the range of 0.002-0.020 inch.

13. The system element of claim 8, wherein the laser rod is selected from the group consisting of a neodymium-doped yttrium aluminum garnet (Nd:YAG) laser rod, a thulium-doped yttrium aluminum garnet (Tm:YAG) laser rod, a ytterbium-doped yttrium aluminum garnet (Yb:YAG) laser rod, and a holmium-doped yttrium aluminum garnet (Ho:YAG) laser rod.

14. The laser system of claim 8, wherein the thermally conductive jacket comprises a reflective surface facing the exterior surface of the laser rod.

15. A method comprising:
delivering a flow of cooling liquid over a laser element comprising a thermally conductive jacket on an exterior surface of a laser rod;
pumping the laser rod with pump energy generated by a pump source;
generating laser light using the laser rod responsive to pumping the laser rod; and
conducting heat from the laser rod to the flow of cooling liquid through the thermally conductive jacket.

16. The method of claim 15, wherein:
the laser rod has a central axis; and
the jacket surrounds the exterior surface of the laser rod extending along the central axis.

17. The method of claim 16, wherein the thermally conductive jacket is bonded to the exterior surface.

18. The method of claim 16, wherein the thermally conductive jacket comprises a metal selected from the group consisting of silver, gold, copper alloy, and aluminum nitride.

19. The method of claim 16, wherein the thermally conductive jacket has a thickness in the range of 0.002-0.020 inch.

20. The method of claim 15, wherein the laser rod is selected from the group consisting of neodymium-doped yttrium aluminum garnet (Nd:YAG), a thulium-doped yttrium aluminum garnet (Tm:YAG) laser rod, a ytterbium-doped yttrium aluminum garnet (Yb:YAG) laser rod, and a holmium-doped yttrium aluminum garnet (Ho:YAG) laser rod.
